(19) United States
(12) Patent Application Publication
(10) Pub. No.: US 2026/0165186 A1
(43) Pub. Date: Jun. 11, 2026

(54) ELECTRONIC DEVICE AND METHOD FOR MANUFACTURING AN ELECTRONIC DEVICE

(71) Applicant: ams-OSRAM International GmbH, Regensburg (DE)

(72) Inventors: Philipp McCaw, Nittendorf (DE); Michael Müller, Eching (DE); Christian Betthausen, Lappersdorf (DE); Harald Jäger, Regensburg (DE); Zeljko Pajkic, Regensburg (DE); Bodo Wallikewitz, Neumarkt i d Opf (DE)

(21) Appl. No.: 18/710,293

(22) PCT Filed: Nov. 16, 2022
(86) PCT No.: PCT/EP2022/082094

§ 371 Date: May 15, 2024

(30) Foreign Application Priority Data
Nov. 18, 2021 (DE) 10 2021 130 173.4

(51) Int. Cl. H10W 74/10; H10W 74/01

(52) U.S. Cl. CPC H10W 74/111; H10W 74/016

(57) ABSTRACT

In an embodiment an electronic device includes a housing body with a cavity in which an electronic semiconductor chip is mounted and a cover element arranged in the cavity and covering the semiconductor chip, wherein the cavity has a side wall, which faces the semiconductor chip, and which surrounds the semiconductor chip in a lateral direction, wherein the cover element is in direct mechanical contact with the side wall in at least one adhesion region and adheres directly to the housing body in the at least one adhesion region, wherein the housing body has at least one anchoring structure configured to reduce a delamination tendency of the cover element from the housing body in the at least one adhesion region, and wherein the anchoring structure comprises a roughening and/or at least one pillar element located on a bottom surface of the cavity.

### CROSS-REFERENCE TO RELATED APPLICATIONS

This patent application is a national phase filing under section 371 of PCT/EP 2022/082094, filed Nov. 16, 2022, which claims the priority of German patent application 102021130173.4, filed Nov. 18, 2021, each of which is incorporated herein by reference in its entirety.

### TECHNICAL FIELD

An electronic device and a method for manufacturing an electronic device are disclosed. The electronic device comprises, in particular, an electronic semiconductor chip in a housing body. The housing body can form at least a part of a so-called package.

### BACKGROUND

Conventional packages have, for example, a plastic housing with a cavity in which at least one semiconductor chip is mounted and, for example, casted with a casting material. The surfaces of the cavity are usually flat and smooth, for example to achieve the highest possible reflectivity, and correspond, for example, to the milled or ground surfaces of the mold used for manufacturing the housing, so that the casting lies flat on flat on these surfaces.

Due to the finite mutual adhesion of the adjoining materials and their different coefficients of thermal expansion (CTE), which can, during temperature changes, cause (interface) stresses to build up which tend to relax, there is a risk of delamination of the casting from the cavity wall and/or of material cracks. Such delamination and cracks represent a quality problem and can, for example, lead to field failures and thus result in high costs.

To reduce the risk of delamination, it is known, for example, to carry out a plasma treatment before filling the casting into the cavity, which can increase the adhesion at the interfaces to the casting. However, plasma treatments of this kind require increased time and money.

### SUMMARY

Embodiments provide an electronic device. Further embodiments provide a method for manufacturing an electronic device.

According to at least one embodiment, an electronic device has a housing body with a cavity in which an electronic semiconductor chip is mounted.

According to at least one further embodiment, in a method for manufacturing an electronic device, a housing body is formed and an electronic semiconductor chip is mounted in the housing body.

The following description equally refers to the electronic device and the method for manufacturing the electronic device.

According to a further embodiment, the electronic semiconductor chip, which can hereinafter also be referred to simply as a semiconductor chip, is an optoelectronic semiconductor chip. In particular, the semiconductor chip can be a light-emitting semiconductor chip such as a light-emitting diode. The electronic device is then correspondingly a light-emitting device. Alternatively or additionally, the electronic device can also comprise a light-absorbing semiconductor chip such as a photodiode chip as the electronic semiconductor chip. In this case, the electronic device can be a light-absorbing device. Furthermore, it is also possible that the electronic semiconductor chip has no optoelectronic properties and is designed as a purely electronic semiconductor chip. Even if an electronic device with exactly one electronic semiconductor chip is described below, the electronic device can also have several identical or different semiconductor chips, which can be arranged and mounted in the cavity. The following description thus also applies accordingly to several semiconductor chips mounted in the cavity.

In particular, the electronic semiconductor chip can be mounted and electrically connected on a mounting surface of the housing body. The direction in which the semiconductor chip is arranged on the mounting surface, which can be part of a base surface of the housing body, is referred to here and in the following as the vertical direction. Directions perpendicular to the vertical direction are referred to here and in the following as lateral directions. Terms such as “top”, “bottom”, “top side” and “bottom side” refer to the vertical direction, unless otherwise specified. Terms such as “next to” refer to a lateral direction, unless otherwise stated.

The housing body can in particular form a part of a so-called package and particularly preferably comprise a plastic material that forms the cavity. For example, the housing body can be part of a so-called QFN package (QFN: “quad flat no leads”) or a so-called premold package, in which lead frame parts are provided for electrical contacting of the semiconductor chip in a plastic housing body. Other housing designs are also possible.

Particularly preferably, at least the part of the housing body that forms the cavity can be manufactured by means of a molding process, for example by injection molding, casting or compression molding. A molding tool is used for the molding process. The molding tool has a molding chamber, for example, which forms a negative mold of the housing body to be molded, possibly with elements to be molded in, such as lead frame parts, inserted into the molding chamber. For example, injection molding or transfer molding is used as the molding process. The material to be molded, in the case of the housing body described here a plastic material, is placed in a chamber of a molding tool. The material to be molded is then pressed into the molding chamber by applying heat and/or pressure. Furthermore, the molding process can also be compression molding, for example. In this process, the material to be formed, in the case of the housing body described here a plastic material, is introduced into the molding chamber of a molding tool. The material to be molded is brought into the desired shape by applying heat and/or pressure. The molding process is preferably carried out in a compound. This means that a contiguous composite of a plurality of housing bodies is produced by means of the molding process, which can be singulated in a later process step by cutting, for example sawing, abrasive cutting or laser cutting.

Depending on the molding process and application of the electronic device, the plastic material for the housing body can be a thermoplastic or a thermoset, for example. For example, the plastic material can comprise siloxanes, epoxides, acrylates, methyl methacrylates, imides, carbonates, olefins, styrenes, urethanes or derivatives thereof in the form of monomers, oligomers or polymers and also mixtures, copolymers or compounds thereof. For example, the plastic material can comprise or be an epoxy resin, polyphthalamide (PPA), polymethyl methacrylate (PMMA), polystyrene, polycarbonate (PC), polyacrylate, polyurethane or a silicone resin such as polysiloxane or mixtures thereof.

The electronic device can further comprise a cover element which is filled into the cavity and which covers the semiconductor chip. Particularly preferably, the semiconductor chip can be encased by the cover element. In particular, this can mean that the semiconductor chip is molded in by the cover element or that the cover element is molded onto the sides of the semiconductor chip that were free before the cover element was applied. In particular, the cover element can be a so-called casting. Here and in the following, casting refers to a material that is filled into the cavity in a viscous form, i.e. in particular in a liquid or partially liquid form, and that is cured simultaneously or subsequently. In particular, a covering material can thus be filled into the cavity to form the cover element. After curing, the casting, i.e. the cover element, can have elastic or thermosetting properties. One of the molding processes described above can be used to fill the covering material into the cavity. Furthermore, the covering material can also be casted into the cavity, for example. For example, the covering material can be a silicone resin or another material previously mentioned in connection with the housing body.

According to a further embodiment, the cavity has a side wall which faces the semiconductor chip and which surrounds the cavity and thus the semiconductor chip in a lateral direction. The side wall can run parallel to the vertical direction and thus be a vertical or essentially vertical side wall. Particularly preferably, the side wall is inclined to the vertical direction and is thus an oblique side wall. An oblique side wall can, for example, be embodied as a reflector which, in the case of a light-emitting device with a light-emitting semiconductor chip, can direct light that is emitted from the semiconductor chip in a lateral direction onto the side wall during operation in the direction of the vertical direction and thus out of the cavity.

According to a further embodiment, the cover element is in direct mechanical contact with the side wall in at least one adhesion region. In the at least one adhesion region, the cover element can adhere directly to the housing body and thus directly to the side wall. In other words, the at least one adhesion region is an area in which there is an adhesive force between the housing body and the cover element at the interface between the housing body and the cover element.

Particularly preferably, the at least one adhesion region comprises at least a part of the side wall of the cavity or the entire side wall. In other words, the cover element adheres in at least one adhesion region directly to a part of the side wall of the cavity or to the entire side wall. Thus, the at least one adhesion region can preferably completely surround the semiconductor chip in the lateral direction.

According to a further embodiment, the housing body has at least one anchoring structure which is intended and configured to reduce a tendency of the cover element to delaminate from the housing body in the at least one adhesion region. In other words, the tendency of the cover element to detach from at least the side wall in the adhesion region can be reduced by the anchoring structure compared to a comparable housing body without the anchoring structure. As described below, the anchoring structure can have microscopic or macroscopic anchoring elements and can in particular be intended and configured to improve the mechanical anchoring of the cover element by creating anchoring elements for stress absorption and/or to improve the adhesion of the cover element in the at least one adhesion region to the housing body by increasing the effective interface. Particularly preferably, the anchoring structure can be a substitute for other additional and often expensive processes such as plasma treatment of the housing body.

The features and embodiments of the anchoring structure described below can be present alone or in combination. In particular, the anchoring structure can have several similar or different anchoring elements as described below.

According to a further embodiment, the anchoring structure is formed in at least one adhesion region. In particular, the anchoring structure can be formed in or on the side surface of the cavity. Particularly preferably, the anchoring structure can have at least one depression and/or elevation in the side wall of the cavity.

For example, the anchoring structure can have a roughening, which can be formed by a plurality of regularly or irregularly arranged elevations and/or depressions. The roughening and thus the elevations and/or depressions can particularly preferably have structure sizes of less than or equal to 100 μm or less than or equal to 50 μm or less than or equal to 20 μm or preferably less than or equal to 15 μm. Furthermore, the roughening and thus the elevations and/or depressions can have structure sizes of greater than or equal to 1 μm or greater than or equal to 2 μm or greater than or equal to 5 μm.

For example, the housing body, which can comprise or be formed from a plastic body as described above, can comprise the roughening at least on all surfaces of the plastic body that are in direct mechanical contact with the cover element. In other words, the entire adhesion region between the housing body and the cover element can comprise the roughening. In addition, other surfaces of the housing body can also comprise a roughening. For example, such roughening, which is preferably present across large areas, can be produced by an etching process or by laser structuring. Furthermore, it is also possible that a film-assisted molding (FAM) process is used to form the housing body and the roughening is formed by the film. This can be achieved, for example, by using a film that has a surface structure corresponding to the roughening. In addition, it can also be possible for the molding tool used to form the housing body to have a surface structure corresponding to the roughening, at least in partial regions, and thus a negative form of the anchoring structure.

According to a further embodiment, the anchoring structure has anchoring elements, particularly preferably in the form of a roughening, which are arranged in the vertical direction on the side wall of the cavity above the semiconductor chip. In particular, the side wall can have an upper region which projects above the semiconductor chip in the vertical direction, the anchoring structure being arranged only in the upper region when viewed from the semiconductor chip in the vertical direction. Thus, if a plane perpendicular to the vertical direction is conceived, which is arranged on the top side of the semiconductor chip delimiting the semiconductor chip in the vertical direction, the upper region and thus the anchoring structure in this case is arranged only above this plane. In simple terms, the anchoring structure is therefore arranged higher than the upper edge of the semiconductor chip. Particularly preferably, the anchoring structure is arranged only in an upper part of the upper region as seen from the semiconductor chip in the vertical direction, wherein the upper part occupies a proportion of less than or equal to 80% or less than or equal to 66% or less than or equal to 50% of the upper region from an upper edge of the side wall. In case of a roughening having such properties, the anchoring structure can preferably be produced by means of the molding process by which the housing body is formed. In particular, a negative mold of the anchoring structure can be provided in the mold for the roughening.

While the roughening described above forms microscopic anchoring elements of the anchoring structure, the anchoring structure can alternatively or additionally also have macroscopic anchoring elements such as those described below. The macroscopic anchoring elements can preferably form undercuts in at least some lateral directions, which allow improved anchoring of the cover element in the cavity.

For example, the anchoring structure can have at least one web running along the side wall. In other words, the side wall contains an elevation that is web-shaped, i.e. preferably has a greater expansion in one direction than in the two directions perpendicular to it. The at least one web can preferably extend in a vertical direction. For example, the web can extend from a bottom surface of the cavity to an upper edge of the cavity. Particularly preferably, the anchoring structure can comprise a plurality of webs extending in a vertical direction, which can be arranged substantially evenly distributed in a lateral direction around the semiconductor chip. It can also be possible for the cavity to have a cross-section that has a square or rectangular basic shape, for example with rounded corners, and for such webs extending in the vertical direction to be arranged at least in the region of the corners.

According to a further embodiment, the anchoring structure has at least one anchoring element that is spaced from the side wall and, in particular, from the adhesion region. In particular, the anchoring structure can have at least one pillar element formed on a bottom surface of the cavity. The pillar element can particularly preferably have an angular or round cross-section and extend vertically upwards from the bottom surface of the cavity. For example, such a pillar element can have a height which, in the vertical direction, is at the same height or lower than an edge delimiting the cavity at the top, so that the pillar element does not protrude from the cover element after the cover element has been applied, and is particularly preferably covered by the cover element. Particularly preferably, the anchoring structure can have a plurality of such pillar elements, which can be arranged symmetrically next to or around the semiconductor chip in the lateral direction.

Anchoring elements such as the described vertically extending webs and the pillar elements can preferably be produced simultaneously with the formation of the housing body by means of the molding process for forming the housing body. For this purpose, the used molding tool can have a negative form of the anchoring structure. To facilitate demolding, the web(s) or the pillar element(s) of the anchoring structure can have a width that decreases in the vertical direction towards the top, measured in the lateral direction. In other words, the vertical webs or the pillar elements can be tapered towards the top and have a truncated pyramid or truncated cone shape.

According to a further embodiment, the anchoring structure has at least one web extending on the side wall in the lateral direction. In particular, the web on the side wall can be formed circumferentially around the semiconductor chip and thus form an elevation circumferentially around the semiconductor chip. Furthermore, the anchoring structure can have at least one groove running laterally in the side wall. In particular, the groove on the side wall can be formed circumferentially around the semiconductor chip and thus form a groove running around the semiconductor chip. Alternatively, a plurality of webs and/or grooves that are separated from one another in the lateral direction and extend in the lateral direction on the side surface of the cavity can also be provided. For example, the anchoring structure can have a plurality of island-shaped elevations and/or blind-hole-like depressions arranged in a bead-chain-like manner in the lateral direction. Such anchoring elements can, for example, be produced using a suitable molding tool as described above or by laser structuring or, alternatively, can be provided as pre-fabricated anchoring elements and applied to the housing body. For example, the anchoring elements can be glued on in this case.

In the embodiments and features of the anchoring structure described above, the covering material particularly preferably has a viscosity and the anchoring structure has a structure size, wherein the structure size and the viscosity are adapted to each other in such a way that the anchoring structure is completely in direct contact with the finished cover element. In other words, the anchoring structure and the covering material are preferably adapted to each other in such a way that the covering material and thus the cover element completely surround the anchoring structure. In particular, the covering material and the structure sizes can be adapted to each other in such a way that no bubbles or voids are created.

### BRIEF DESCRIPTION OF THE DRAWINGS

Further advantages, advantageous embodiments and further developments become apparent from the embodiments described below in conjunction with the figures.

FIG. 1 shows a schematic illustration of a method for manufacturing an electronic device according to an embodiment;

FIGS. 2A to 2C show schematic illustrations of an electronic device according to a further embodiment;

FIGS. 3A and 3B show schematic illustrations of an electronic device according to a further embodiment;

FIG. 4 shows a schematic illustration of a method step of a method for manufacturing an electronic device according to a further embodiment;

FIGS. 5A to 5C show schematic illustrations of an electronic device according to a further embodiment;

FIGS. 6A to 6C show a schematic illustration of a method step of a method for manufacturing an electronic device according to a further embodiment as well as images of surfaces with roughening;

FIGS. 7A and 7B show schematic illustrations of an electronic device according to a further embodiment;

FIGS. 8A and 8B show schematic illustrations of an electronic device according to a further embodiment;

FIGS. 9A and 9B show schematic illustrations of an electronic device according to a further embodiment; and

FIGS. 10A and 10B show schematic illustrations of an electronic device according to a further embodiment.

### DETAILED DESCRIPTION OF ILLUSTRATIVE EMBODIMENTS

In the embodiments and figures, identical, similar or identically acting elements are provided in each case with the same reference numerals. The elements illustrated and their size ratios to one another should not be regarded as being to scale, but rather individual elements, such as for example layers, components, devices and regions, may have been made exaggeratedly large to illustrate them better and/or to aid comprehension.

In connection with the figures described below, the electronic device and methods for manufacturing the same are explained according to several embodiments, wherein in the embodiments, purely by way of example and without limiting the invention, exactly one electronic semiconductor chip is arranged in a housing body, which is embodied, for example, as a light-emitting semiconductor chip such as a light-emitting diode. Alternatively, however, it is also possible for the electronic semiconductor chip to be embodied as a light-absorbing semiconductor chip such as a photodiode or as another optoelectronic semiconductor chip or also as a purely electronic semiconductor chip without an optoelectronic function. Furthermore, more than one semiconductor chip can also be present in the housing body.

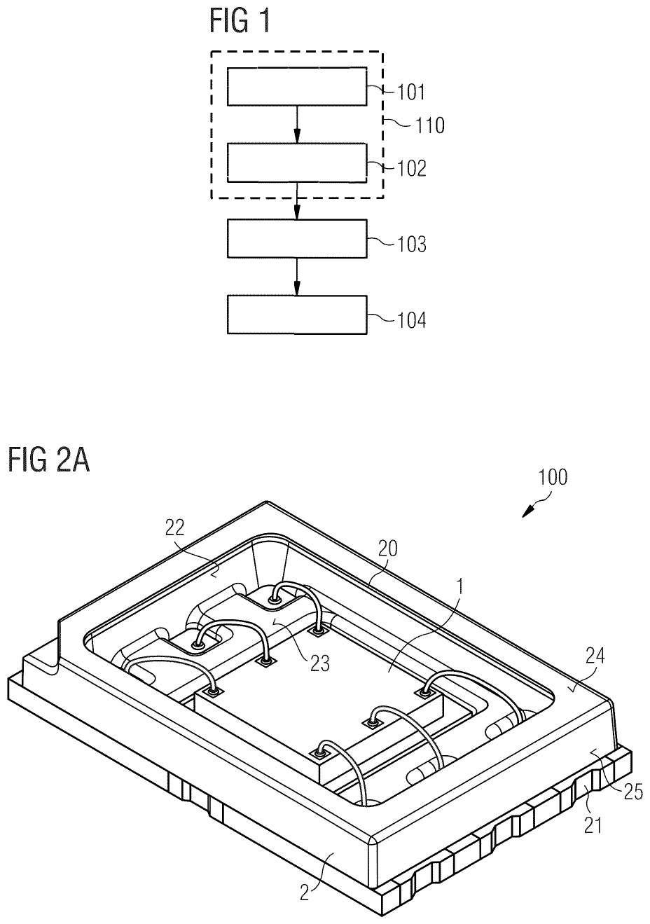

FIG. 1 shows a method for manufacturing an electronic device, in which a housing body with a cavity is formed in a first method step 101. In particular, the housing body can be formed by means of a molding process using a suitable molding tool. Furthermore, as part of the method, an anchoring structure is formed in the housing body, as indicated in a further method step 102. As is explained below, the method steps 101 and 102 can also be carried out simultaneously as part of a common method step 110, as is indicated in FIG. 1. In a further process step 103, an electronic semiconductor chip is mounted in the cavity of the housing body. Furthermore, the semiconductor chip can also be electrically connected here. In a further method step 104, a covering material is filled into the cavity to form a cover element. Further features of the method and the electronic device become apparent from the embodiments shown in connection with the further figures.

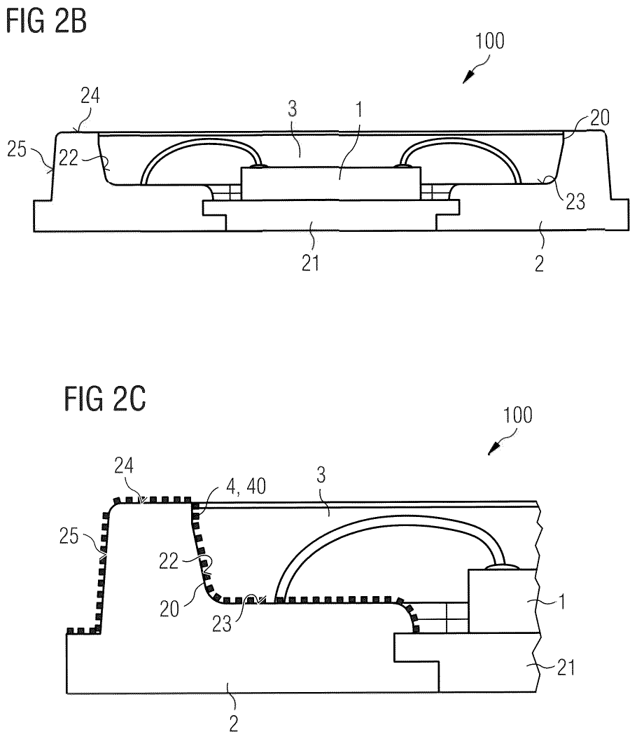

FIGS. 2A to 2C show a three-dimensional top view, a sectional view and a section of the sectional view of an embodiment of an electronic device 100 with an electronic semiconductor chip 1. The following description refers equally to FIGS. 2A to 2C.

By way of example only, the electronic device 100 is embodied as a so-called QFN package and has a housing body 2 with a cavity 20, which comprises a plastic material in which electrical and/or thermal connection elements 21, for example formed by a lead frame, are contained for electrical contacting of the electronic semiconductor chip 1 arranged in the cavity by means of which the electronic device 100 can also be soldered onto a carrier such as a circuit board. The electronic semiconductor chip 1 is mounted purely by way of example on a lead frame piece provided as a heat sink, which forms a mounting surface of the housing body 2, by means of an adhesive or solder and is electrically connected to further lead frame pieces by means of bonding wires. Instead of a QFN package, the electronic device 100 can also have a different design.

The direction in which the semiconductor chip 1 is arranged on the mounting surface is referred to here and in the following as the vertical direction. Directions perpendicular to the vertical direction are referred to as lateral directions.

The plastic material for the housing body 2 can, for example, be a thermoset such as a white or black epoxy, also known as EMC (“epoxy mold compound”), and/or PPA and/or PC. Alternatively, however, other plastic materials are also possible. The housing body 2 can be manufactured by means of a suitable molding process, for example a method described above in the general part. In particular, the molding process can be used to manufacture a plurality of housing bodies 2 in the form of a composite, which can then be singulated in a later process step.

A cover element 3 is arranged in the cavity 20, which is omitted in FIG. 2A in order to be able to show the elements arranged in the cavity. The cover element 3 is filled into the cavity 20 and covers the semiconductor chip 1. As can be seen in FIG. 2B, the semiconductor chip 1 can be particularly preferably encapsulated by the cover element 3. In particular, the cover element 3 can be a casting material and is filled into the cavity 20 as a covering material in a liquid or partially liquid form and cured simultaneously or subsequently. For example, the cover element 3 can have or be a silicone resin. Alternatively, other plastic materials as described above in the general part are also possible.

The cavity 20 has a side wall 22 which faces the semiconductor chip 1 and which surrounds the cavity and thus the semiconductor chip 1 in the lateral direction. The side wall 22 can be a vertical or substantially vertical side wall or, as shown, an oblique side wall. An oblique side wall can, for example, be formed as a reflector which, in the case of a light emitting device with a light emitting semiconductor chip, can direct light emit in a lateral direction from the semiconductor chip 1 onto the side wall 22 in the direction of the vertical direction and thus out of the cavity during operation. In this case, the cover element 3 can be transparent or translucent and can also contain, for example, a phosphor that converts at least part of the light emitted by the semiconductor chip 1 during operation into light of a different wavelength.

As can be seen in FIGS. 2B and 2C, the cover element 3 is in direct mechanical contact with the housing body 2 at the side wall 22 and the bottom surface 23. Areas with such direct mechanical contact are referred to here and in the following as adhesion regions, since the cover element 3 can adhere directly to the housing body 2 in an adhesion region. The adhesion region can include at least a portion of the side wall 22 of the cavity 20 and, as shown, particularly preferably the entire or at least substantially the entire side surface 22. Furthermore, in the embodiment shown, the adhesion region also includes the bottom surface 23 of the housing body 2, which in the embodiment shown forms at least partially a so-called glue-creep barrier (GCP), which prevents adhesive or solder, with which the semiconductor chip 1 is attached as described above, from creeping to the areas in which the bonding wires are electrically connected. Thus, in the embodiment shown, the adhesion region completely surrounds the semiconductor chip 1 in the lateral direction.

The electronic device according to the present and the following embodiments further comprises an anchoring structure intended and configured to reduce a delamination tendency of the cover element from the housing body in the adhesion region. The anchoring structure can have microscopic or macroscopic anchoring elements 40, as described in more detail below, and can in particular be intended and configured to affect an improvement in the mechanical anchoring of the cover element 3 by creating anchoring elements for stress absorption and/or an improvement in the adhesion of the cover element 3 in the at least one adhesion region to the housing body 2 by increasing the effective interface.

In the embodiment shown, the anchoring structure 4 is formed as a roughening 40 on the entire adhesion region, i.e. on the entire side surface of the cavity and the bottom surface, as indicated in FIG. 2C by the exaggerated structure. The anchoring structure thus has as anchoring elements a plurality of regularly or irregularly arranged elevations and/or depressions, which can comprise particularly preferred structure sizes of less than or equal to 100 μm or less than or equal to 50 μm or less than or equal to 20 μm or preferably less than or equal to 15 μm as well as greater than or equal to 1 μm or greater than or equal to 2 μm or greater than or equal to 5 μm. The roughening 40 can lead to an effective increase in the interface between the cover element 3 and the housing body 2 and thus to improved adhesion between them.

In the embodiment shown, a top side 24 of the housing body 2 and a part of an outer surface 25 of the housing body 2 are also provided with the roughening 40. Only a part of the outer surface 25, on which the composite of housing bodies 2 has been singulated, for example by sawing, and the bottom side of the housing body 2 are free of the roughening 40.

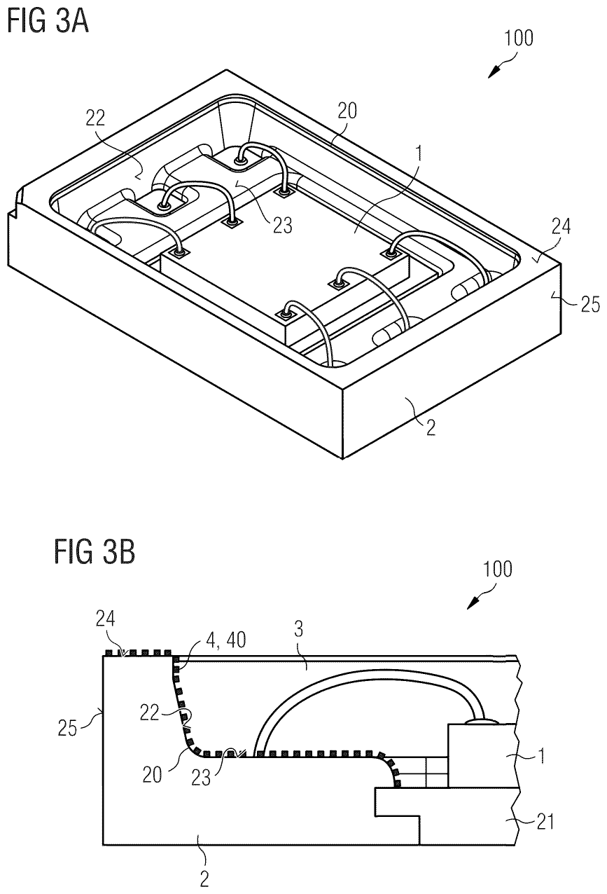

In FIGS. 3A and 3B, corresponding to the views in FIGS. 2A and 2C, views of a further embodiment for the electronic device 100 are shown, in which the entire outer surfaces 25 are formed without roughening 40 due to singulation, for example by sawing.

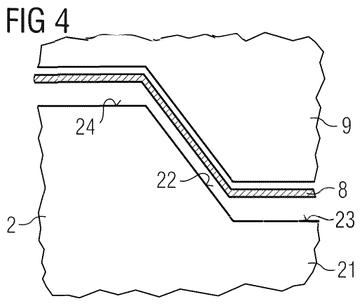

For example, the anchoring structure 4 formed by a roughening 40, which is preferably present across large areas, can be produced by an etching process after the molding process to form the housing body 2 and in particular the housing body composite, in order to achieve the previously described increase in the interface area. Furthermore, it is also possible, as indicated in a section in FIG. 4, that a film-assisted molding (FAM) process is used to mold the housing body 2 and the roughening is formed by the film 8. For this purpose, a film 8 having a surface structure corresponding to the roughening 40 is inserted into a molding tool 9 for producing the housing body 2 as part of the molding process. Such a so-called mold film has a surface facing the thermoplastic or thermoset material of the housing body 2 with a large surface roughness, which allows easy demolding and easy removal of the film 8. For better clarity, the molding tool 9, the film 8 and the formed housing body 2 are shown spaced apart from each other in FIG. 4. Furthermore, it is also possible that the molding tool 9 used to form the housing body 2 has, at least in partial regions, a surface structure corresponding to the roughening 40 and thus a negative shape of the anchoring structure 4. This can be produced by selective etching or laser structuring, for example.

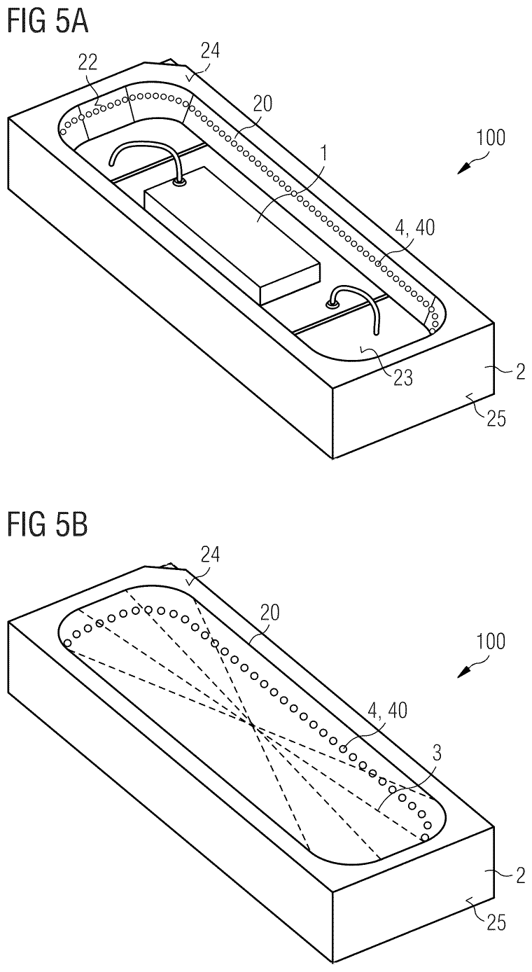

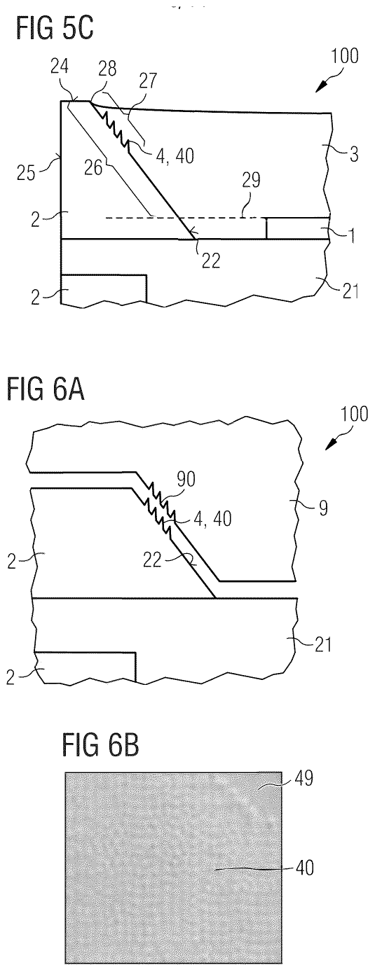

FIGS. 5A and 5B show three-dimensional plan views and FIG. 5C shows a sectional view of a further embodiment of the electronic device 100. In FIG. 5A, compared to FIG. 5B, the cover element 3 is not shown in order to be able to show the elements arranged in the cavity 20. Compared to the two previous embodiments, in this embodiment, the anchoring structure 4 has a roughening 40 that is not formed on the entire side wall 22 of the cavity 20 of the housing body 2. In particular, in the embodiment shown, the roughening 40 is only formed in a partial region of the side wall 22 of the cavity 20 and is not otherwise formed on any surface of the housing body 2.

In particular, as shown in FIG. 5C, the side wall 22 has an upper region 26 which projects above the semiconductor chip 1 in the vertical direction, wherein the anchoring structure 4 is arranged only in the upper region 26 when viewed from the semiconductor chip 1 in the vertical direction. Thus, if a plane 29 perpendicular to the vertical direction is assumed, which is arranged on the top side of the semiconductor chip delimiting the semiconductor chip 1 in the vertical direction and which thus corresponds in its position to the height of the semiconductor chip 1, the upper region 26 and thus the anchoring structure 4 is arranged in this case only above this plane 29. The anchoring structure 4 is thus arranged higher than the upper edge of the semiconductor chip 1. Particularly preferably, the anchoring structure 4 is arranged only in an upper part 27 of the upper region 26 as seen from the semiconductor chip 1 in the vertical direction, the upper part 27 occupying a proportion of less than or equal to 80% or less than or equal to 66% or less than or equal to 50% of the upper region 26 from a top edge 28 of the side wall 22.

The anchoring structure 4 formed by the roughening 40 is in the form of a ribbon running laterally around the semiconductor chip 1. The width of the ribbon can, for example, be greater than or equal to 10 μm and less than or equal to 100 μm. Instead of the embodiment shown with one ribbon, several ribbons with a circumferential roughening 40 can also be provided. Furthermore, an embodiment in the form of a periodically interrupted ribbon, i.e. separated areas with the roughening 40, is also possible.

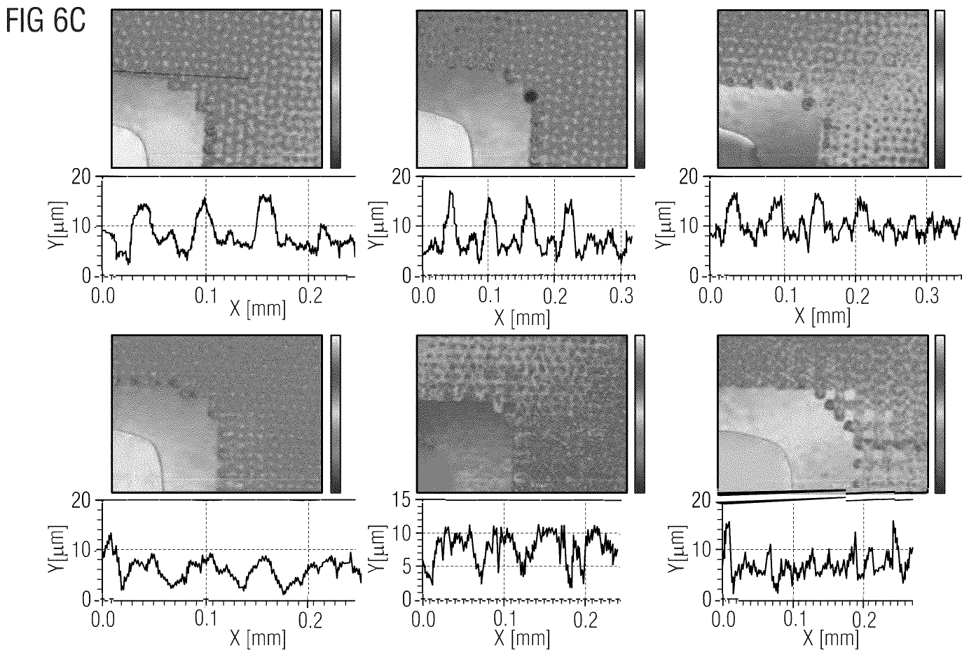

The anchoring structure 4 according to the embodiment of FIGS. 5A to 5C can be produced by means of the molding process with which the housing body 2 is formed. In particular, a negative mold 90 of the anchoring structure 4 can be provided in the molding tool 9 for the roughening 40, as shown in FIG. 6A. The negative mold 90 for the anchoring structure 4 can, for example, be introduced into the molding tool 9 by means of laser structuring. Similar to the preceding embodiments, at least the entire side wall 22 can also be provided with the roughening 40 in this manner.

As in the previous embodiments, the roughening 40 can preferably have structure sizes of less than or equal to 100 μm or less than or equal to 50 μm or less than or equal to 20 μm or preferably less than or equal to 15 μm and of greater than or equal to 1 μm or greater than or equal to 2 μm or greater than or equal to 5 μm, wherein the roughening 40 is formed by correspondingly dimensioned elevations and/or depressions.

FIG. 6B shows a microscope image of a section of a planar epoxy surface, generated by such a molding tool, with a roughening 40 and a non-roughened region 49. The image shows a section with a side length of approximately 0.5 mm. FIG. 6C shows further corresponding images as well as additional height profiles with roughenings with different structure sizes.

In addition or as an alternative to a roughening 40, the anchoring structure 4 can also have larger anchoring elements, which preferably form undercuts in suitable directions in order to achieve anchoring of the cover element 3.

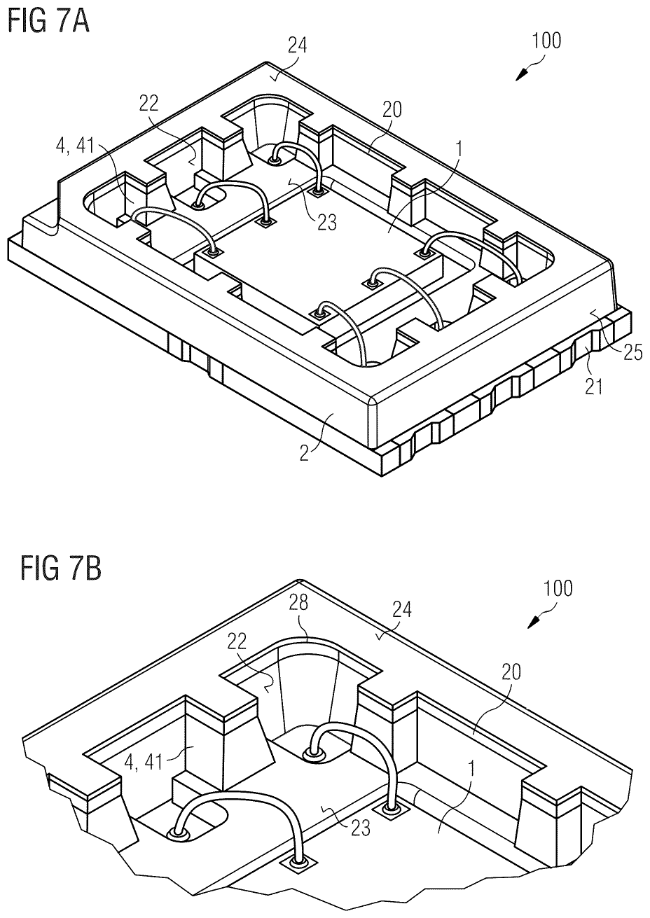

FIGS. 7A and 7B show a three-dimensional top view and a section thereof of an embodiment of the electronic device 100, in which the anchoring structure 4 has at least one web 41 extending along the side wall 22. The cover element is not shown in FIGS. 7A and 7B, nor in part in the following figures.

In particular, the side wall 22 includes elevations that are web-shaped and that extend in a vertical direction in the embodiment shown. As shown, a web 41 can extend from the bottom surface 23 of the cavity 20 to the top edge 28 of the cavity 20.

Particularly preferably, the anchoring structure 4 has a plurality of webs 41 extending in the vertical direction, which can be arranged substantially evenly distributed around the semiconductor chip 1 in the lateral direction. In particular, it can be advantageous if the cavity 20 has a cross-section as shown, which has a square or rectangular basic shape, for example with rounded corners, and the webs 41 extending in the vertical direction are arranged in the region of the corners. In particular, the webs 41 can be positioned where high stresses, in particular lateral stresses, can occur in the cover element or at the interface between the cover element and the housing body 2. As shown, their position can be selected particularly preferably, for example on the GCB, so that they do not require any additional space and therefore the component size, the so-called footprint, of the electronic device 100 does not have to be increased.

The webs 41 of the anchoring structure 4 are preferably produced in one piece with the rest of the housing body 2 and thus by means of the molding process for forming the housing body 2. The molding tool used for this purpose has a negative mold of the anchoring structure 4. To facilitate demolding, the webs 41 can, as indicated, have a width that decreases in the vertical direction towards the top, measured in the lateral direction. In other words, the vertical webs 41 can be conical towards the top and have a truncated pyramid-like shape and thus taper towards the top.

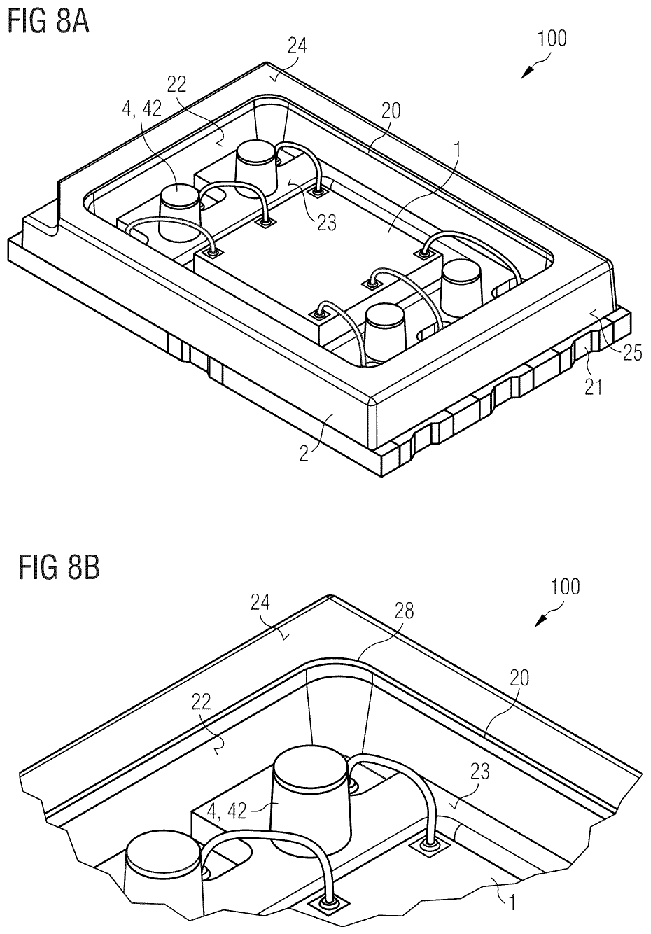

FIGS. 8A and 8B show a further embodiment in which the anchoring structure 4 has anchoring elements spaced from the side wall 22 and, in particular, from the adhesion region. For this purpose, the anchoring structure 4 can comprise one or more pillar elements 42 formed on a bottom surface 23 of the cavity 20. The pillar element or elements 42 can particularly preferably have an angular or round cross-section and extend vertically upwards from the bottom surface 23 of the cavity 20. For example, the pillar elements 42 can have a height that is at the same height or lower in the vertical direction than the top edge 28 delimiting the cavity 20 at the top, so that the pillar elements 42 do not protrude from the cover element after the cover element has been applied and are particularly preferably covered by the cover element.

Particularly preferably, the anchoring structure 4 can have a plurality of pillar elements 42 as shown, which are arranged symmetrically in the lateral direction next to or around the semiconductor chip 1. As already described for the webs 42, the pillar elements 42 can also have an upwardly tapered shape. Such pillar elements 42 defined by the molding tool within the cavity 20, for example on the GCB, enable the cover element and housing body 2 to interlock and thus ideally absorb stresses, in particular stresses in the lateral direction.

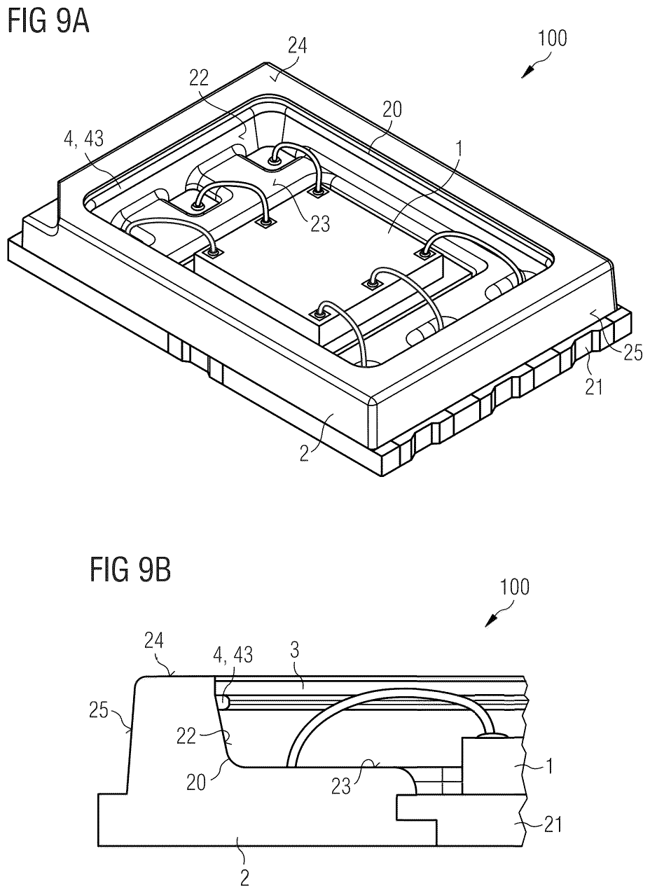

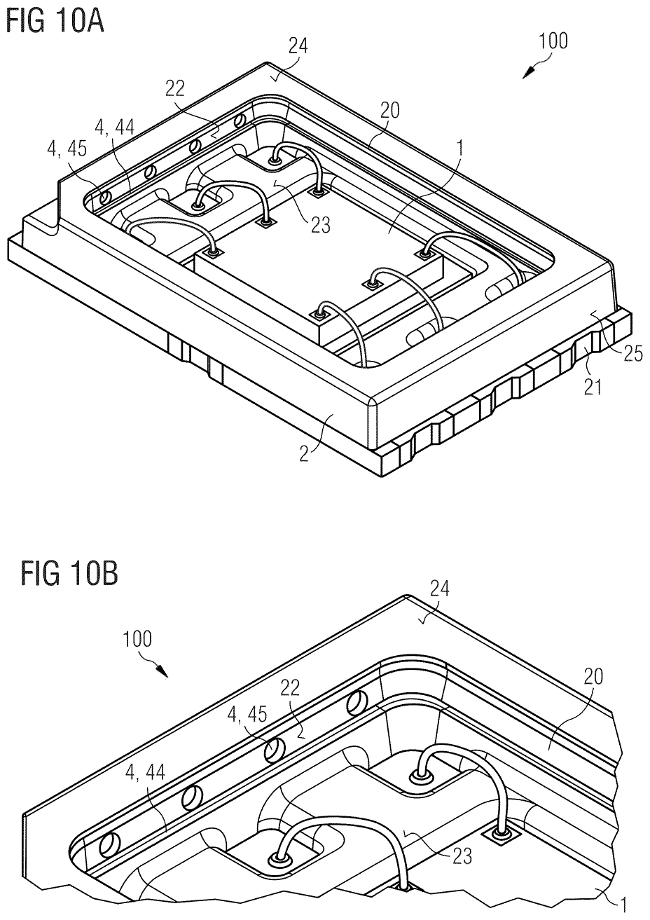

FIGS. 9A and 9B show a further embodiment in which the anchoring structure 4 has a web 43 extending on the side wall 22 in the lateral direction. In particular, the web 43 can be formed circumferentially around the semiconductor chip 1 on the side wall 22 as shown and thus can form an elevation circumferentially around the semiconductor chip 1. As shown in FIGS. 10A and 10B, the anchoring structure 4 can also have at least one groove 44 extending in the lateral direction in the side wall 22. In particular, the groove 44 on the side wall 22 can be formed circumferentially around the semiconductor chip 1 and thus form a circumferential groove 44 around the semiconductor chip 1. Instead of a circumferential web 43 and/or a circumferential groove 44 or in addition to these, the anchoring structure 4 can have a plurality of island-shaped elevations arranged in a bead-chain-like manner in the lateral direction, for example in the form of nubs, and/or blind hole-like depressions 45. Such depressions 45 are additionally provided in the embodiment of FIGS. 10A and 10B. Such anchoring elements can, for example, be produced by means of a suitable molding tool as described above or by laser structuring or, alternatively, can also be provided as pre-fabricated anchoring elements and applied to the housing body 2. For example, the anchoring elements can be glued on in this case. Dimples, webs, grooves and/or blind holes that adhere well to the side wall, for example by additive manufacturing, can be enclosed by the cover element or the cover element can fill them so that it is well anchored in the cavity 20. While a circumferential web 43 and a circumferential groove 44 can provide good anchoring, particularly in the vertical direction, blind-hole-like depressions and dimples can also provide good anchoring in the lateral direction.

The features and embodiments described in connection with the figures can be combined with one another according to further embodiments, even if not all combinations are explicitly described. Furthermore, the embodiments described in connection with the figures can alternatively or additionally have further features as described in the general part.

The invention is not limited to the description based on the embodiments. Rather, the invention includes any new feature as well as any combination of features, which includes in particular any combination of features in the patent claims, even if this feature or combination itself is not explicitly stated in the patent claims or embodiments.

1.-13. (canceled)

14. An electronic device comprising:
a housing body with a cavity in which an electronic semiconductor chip is mounted; and
a cover element arranged in the cavity and covering the semiconductor chip,
wherein the cavity has a side wall, which faces the semiconductor chip, and which surrounds the semiconductor chip in a lateral direction,
wherein the cover element is in direct mechanical contact with the side wall in at least one adhesion region and adheres directly to the housing body in the at least one adhesion region,
wherein the housing body has at least one anchoring structure configured to reduce a delamination tendency of the cover element from the housing body in the at least one adhesion region, and
wherein the anchoring structure comprises a roughening and/or at least one pillar element located on a bottom surface of the cavity.

15. The electronic device according to claim 14, wherein the at least one adhesion region completely surrounds the semiconductor chip in the lateral direction.

16. The electronic device according to claim 14, wherein the anchoring structure surrounds the semiconductor chip in the lateral direction.

17. The electronic device according to claim 14, wherein the anchoring structure comprises at least one depression and/or elevation in the side wall of the cavity.

18. The electronic device according to claim 14,
wherein the housing body comprises a plastic material, and
wherein the roughening is located at least on all surfaces of the plastic material, which are in direct mechanical contact with the cover element.

19. The electronic device according to claim 14,
wherein the side wall has an upper region projecting above the semiconductor chip in a vertical direction,
wherein the anchoring structure is arranged only in an upper part of the upper region as viewed from the semiconductor chip in the vertical direction, and
wherein the upper part occupies a proportion of less than or equal to 80% of the upper region from an top edge of the side wall.

20. The electronic device according to claim 14, wherein the anchoring structure comprises at least one web extending on the side wall in a vertical direction.

21. The electronic device according to claim 14, wherein the anchoring structure comprises at least one web extending on the side wall in the lateral direction.

22. The electronic device according to claim 14, wherein the anchoring structure comprises at least one groove extending in the side wall in the lateral direction.

23. The electronic device according to claim 14, wherein the anchoring structure comprises a plurality of island-shaped elevations and/or blind-hole-like depressions arranged in a bead-chain-like manner in the lateral direction.

24. A method for manufacturing the electronic device according to claim 14, the method comprising:
forming the housing body with the cavity by a molding process using a molding tool;
producing the anchoring structure by the molding process, wherein a film-assisted molding process with a film is used, and wherein the anchoring structure comprises the roughening formed by the film,
mounting the electronic semiconductor chip in the cavity; and
filling a covering material into the cavity to form the cover element.

25. The method according to claim 24,
wherein the covering material has a viscosity and the anchoring structure has a structure size, and
wherein the structure size and the viscosity are adapted to each other such that the anchoring structure is completely in direct contact with the finished cover element.

26. A method for manufacturing the electronic device according to claim 14, the method comprising:
forming the housing body with the cavity by molding process using a molding tool;
producing the anchoring structure by an etching process or by a laser structuring or by attaching one or more pre-fabricated anchoring elements to the housing body by the molding process;
mounting the electronic semiconductor chip in the cavity; and
filling a covering material into the cavity to form the cover element.

27. The method according to claim 26,
wherein the covering material has a viscosity and the anchoring structure has a structure size, and
wherein the structure size and the viscosity are adapted to each other such that the anchoring structure is completely in direct contact with the finished cover element.
